(19) United States
(12) Patent Application Publication
(10) Pub. No.: US 2023/0089477 A1
(43) Pub. Date: Mar. 23, 2023

(54) WIRE DOWN DETECTION SYSTEM AND METHOD

(71) Applicant: PACIFIC GAS AND ELECTRIC COMPANY, San Francisco, CA (US)

(72) Inventors: Eric Schoenman, San Francisco, CA (US); Lisa Gayle Kwietniak, Hercules, CA (US); Divya Gopalpet, San Ramon, CA (US); Ravi Shankar Nair, Fremont, CA (US); Akhil Katkol, Dublin, CA (US)

(21) Appl. No.: 17/950,720

(22) Filed: Sep. 22, 2022

Related U.S. Application Data
(60) Provisional application No. 63/247,129, filed on Sep. 22, 2021.

(51) Int. Cl. G01R 19/25; G01R 22/10

(52) U.S. Cl. CPC G01R 19/2513; G01R 22/10

(57) ABSTRACT

Some embodiments include a system for metering an electrical grid comprising at least one processor executing instructions from a non-transitory computer-readable storage medium of an electrical grid fault detection system. In some embodiments of the system, the instructions cause a processor to calculate a prediction of whether power delivery to at least a portion of the electrical grid is functioning abnormally using voltage sensing devices coupled to at least one feeder, where one or more of the voltage sensing devices are responsive to a determination that the power delivery is functioning abnormally. Further in some embodiments, the determination includes the electrical grid fault detection system receiving at least one signal or voltage reading from the electrical grid based at least in part on a sensed or received voltage level or range of voltage level.

### CROSS-REFERENCE TO RELATED APPLICATION

This application claims the benefit of and priority to U.S. Provisional Application No. 63/247,129, filed Sep. 22, 2021, which is incorporated herein by reference in its entirety.

### BACKGROUND

Utilities often deploy automatic outage detection tools to indicate a power service outage. However, unless there is a customer hazard call, the utility company often cannot differentiate between an energized wire down or a complete power outage. The ability to more definitively identify the type of outage fault can contribute to improving overall safety standing with utility customers by reducing the time it takes to identify, secure, and repair any potentially hazardous faults. For example, overall safety can be increased by reducing the time it takes to identify, secure, and repair faults, and more accurately identify locations where there may be customer damage. Moreover, distribution or dispatch operators can prioritize restoration responses to locations with clearly identified safety hazards, such as those presented by a downed, energized wire.

### SUMMARY

Some embodiments include a computer-implemented method of metering an electrical grid comprising at least one processor executing instructions from a non-transitory computer-readable storage medium of an electrical grid fault detection system. In some embodiments, the instructions cause a processor to calculate a prediction of whether power delivery to at least a portion of the electrical grid is functioning abnormally using electrical meters coupled to at least one feeder, where one or more of the electrical meters are responsive to a determination that the power delivery is functioning abnormally. In some embodiments, the response following the determination includes the electrical grid fault detection system receiving at least one signal or voltage reading from the electrical grid based at least in part on a sensed or received voltage level or range of voltage level.

In some embodiments, the computer-implemented method includes querying one or more of the electrical meters, where the querying precedes the receipt of the signal or voltage from at least one electrical meter, and the signal or voltage is at least partially based on the query. In some embodiments, asynchronous communication of abnormal voltage by one or more devices may be followed by querying additional devices for supplemental analytical data including, but not limited to, voltage, voltage range, or device state. In some further embodiments, the functioning abnormally includes a voltage change above or below the voltage level or range of voltage level. In other embodiments, the functioning abnormally includes a power failure event. In some further embodiments, the functioning abnormally is indicative of a downed wire that is energized. In some other embodiments, the functioning abnormally is indicative of a downed wire that is not energized.

In some embodiments, the signal or voltage reading originates from an electrical meter coupled to a single transformer of the electrical grid. In some embodiments, the signal or voltage reading originates from two or more electrical meters coupled to the same transformer of the electrical grid. In some further embodiments, the functioning abnormally is indicative of the voltage level or range of voltage level being about 75% to 90% of nominal. In other embodiments, the functioning abnormally is indicative of the voltage level or range of voltage level being about 25% to 75% of nominal. In some embodiments, the functioning abnormally is indicative of the voltage level or range of voltage level being less than about 25% of nominal.

In some embodiments, the determination includes an on-demand read of the electrical meters. In some embodiments, the determination includes an on-demand read of a plurality of electrical meters. In some embodiments, the plurality is a total of six meters plus 25% of the total number of meters of a feeder of the electrical grid. In some further embodiments, the on-demand read comprises a real-time or near real-time meter request for kWh usage data and voltage data. In some embodiments, the determination includes a check for the feeder being three-wire or four-wire.

In some embodiments, the functioning abnormally is a feedback condition comprising at least one of a broken wire, a burnt-out jumper, and a single fuse operating on a two or three wire line. In some further embodiments, the functioning abnormally is an arc detection with at least one of line sensors and substation relays, the line sensors providing at least one of fault location, real-time load, and verification of voltage present on one or all phases.

Some embodiments include a non-transitory computer-readable storage medium, storing instructions that, when executed, cause a processor to perform a computer-implemented method of operating an electrical grid comprising calculating a prediction of whether power delivery to at least a portion of the electrical grid is functioning abnormally using electrical meters coupled to at least one feeder, where one or more of the electrical meters are responsive to a determination that the power delivery is functioning abnormally. In some embodiment of the medium, the determination includes the electrical grid fault detection system receiving at least one signal or voltage reading from the electrical grid based at least in part on a sensed or received voltage level or range of voltage level.

Some further embodiments include a system for metering an electrical grid comprising at least one processor executing instructions from a non-transitory computer-readable storage medium of an electrical grid fault detection system. In some embodiments of the system, the instructions cause a processor to calculate a prediction of whether power delivery to at least a portion of the electrical grid is functioning abnormally using electrical meters coupled to at least one feeder, where one or more of the electrical meters are responsive to a determination that the power delivery is functioning abnormally. Further in some embodiments, the determination includes the electrical grid fault detection system receiving at least one signal or voltage reading from the electrical grid based at least in part on a sensed or received voltage level or range of voltage level.

In some embodiments, the disclosure includes a system for multiphase meter anomaly detection. In some embodiments, the system comprises one or more electrical meters and one or more power lines. In some embodiments, the one or more power lines are configured to transmit electrical power to the one or more electrical meters. In some embodiments, the one or more electrical meters are configured to detect the presence of multiple phases within the electrical power. In some embodiments, each of the one or more electrical meters comprise one or more meter computers comprising one or more meter processors and one or more meter non-transitory computer readable media, the one or more meter non-transitory computer readable media comprising instructions stored thereon that when executed cause the one or more computers to generate, by the one or more meter processors, an anomaly signal associated with at least one phase of the multiple phases even if one or more other phases of the multiple phases are still energized.

In some embodiments, the system is configured to use an internal anomaly detection alert from the one or more meters to generate the anomaly. In some embodiments, the system is able to detect a wire down condition comprising a deenergized power line in a 3 wire electrical distribution system. In some embodiments, the 3 wire distribution system comprises 3 phases and no neutral wire. In some embodiments, the system is able to detect a wire down condition in a 4 wire distribution system. In some embodiments, the 4 wire distribution system comprises 3 phases and a neutral wire.

In some embodiments, the one or more electrical meters comprises one or more smart meters. In some embodiments, the system is configured to use the one or more smart meters to detect a location of a broken electrical utility component on an electrical distribution circuit. In some embodiments, the electrical distribution circuit includes one or more electrical utility components located external to the one or more smart meter's internal components. In some embodiments, the one or more electrical meters are a 3 phase electrical meters. In some embodiments, the system is configured to use discovery signals from one or more electrical meters to determine if one of the phases has lost voltage. In some embodiments, the instructions cause the one or more smart meter computers to send, by one or more meter processors, unsolicited messages when abnormal conditions are detected.

In some embodiments, each of the one or more electrical meters comprises a circuit board comprising a plurality of input pins. In some embodiments, the one or more meter computers are configured to monitor an active and inactive status of at least one of the plurality of input pins through a discovery signal. In some embodiments, the discovery signals are used to detect partial out circuits on a 3 wire distribution circuit. In some embodiments, the discovery signals are used to detect partial out circuits on 4 wire distribution circuits. In some embodiments, the at least one of the input pins is configured to detect a voltage fluctuation and/or voltage outages occurring in one or more input phases. In some embodiments, the meter computer is configured to identify an abnormal power condition using a signal from at least one of the plurality of input pins.

In some embodiments, the system is configured to determine an approximate location of a power loss in a power line using one or more electrical meters. In some embodiments, the one or more electrical meters comprise two or more electrical meters. In some embodiments, the system is configured to determine an approximate location of a power loss in a power line using the two or more electrical meters. In some embodiments, the system is configured to determine which phase in a multiphase power transmission has lost power at the location. In some embodiments, the one or more power lines transmit electrical power from an electrical power source (e.g., electrical power plant) upstream through one or more electrical components located at various locations to a downstream electrical power sink (e.g., home appliance). In some embodiments, at least a first electrical meter of the two or more electrical meters is located upstream of the approximate location. In some embodiments, at least a second electrical meter of the two or more electrical meters is located downstream of the approximate location. In some embodiments, the system is configured not send the anomaly signal if a partial voltage event is logged for less than a predetermined period of time.

In some embodiments, the instructions are configured to send the anomaly signal to a command center. In some embodiments, the command center comprises one or more command center computers comprising one or more command center processors and one or more command center non-transitory computer readable media, wherein the one or more command center computers are configured to monitor and/or control one or more components in an electrical distribution system.

In some embodiments, wherein the one or more meter computers comprise a network interface card (NIC). In some embodiments, wherein the meter computer is configured to identify a loss of (exactly) 1 of 3 phases using a signal from at least one of the plurality of input pins. In some embodiments, the meter computer is configured to identify a possible loss of one or more phases using a signal from at least two of the plurality of input pins.

In some embodiments, a trap includes the anomaly signal. In some embodiments, the one or more meter computers are configured to send an anomaly message to the command center if a partial voltage event is logged for more than a predetermined period of time. In some embodiments, the electrical distribution system is configured to deliver electrical power comprising multiple phases. In some embodiments, the electrical distribution system comprises a plurality of transformer, power lines, electrical towers, poles, (electrical smart) meters, and/or substations. In some embodiments, the one or more command center computers are configured to be accessed by one or more remote client computers. In some embodiments, the electrical distribution system comprises electrical meters both upstream and downstream of an electrical component, wherein the electrical component comprises at least one of a power line, a power line pole, a power line tower, a transformer, a power generator, a power substation, as well as associated substructures and/or conventional electrical distribution structures.

In some embodiments, the one or more meter computers are configured to not send an anomaly message to the command center if a partial voltage event is logged for less than a predetermined period of time. In some embodiments, the one or more meter computers are configured to send second anomaly message to the command center if a partial voltage event comprises a voltage drop below a predetermined threshold is then restored to a voltage above the predetermined voltage threshold for less than a predetermined period of time before falling again below the predetermined threshold. In some embodiments, the one or more meter computers are configured to send an anomaly signal (e.g., message) to the command center if a partial voltage event is logged as cleared for less than a predetermined period of time. In some embodiments, the anomaly signal includes an anomaly detection time.

In some embodiments, the meter computer is configured to check the status of one or more phases when the signal from at least one of the plurality of input pins is received. In some embodiments, the system comprises a command center configured to receive data from one or more meters. In some embodiments, each meter is configured to report an abnormal power condition via the anomaly signal. In some embodiments, each report includes a status of a power phase being monitored by the meter. In some embodiments, the system is configured to determine an approximate location where a loss of power in one or more phases occurs using one or more of each report. In some embodiments, the system is configured to send the approximate location to the command center. In some embodiments, the system is configured to alert a user of the approximate location. In some embodiments, the system is configured to determine which of one or more phases has lost power.

### DESCRIPTION OF THE DRAWINGS

FIG. 1 illustrates a high impedance fault implementation according to some embodiments.

FIG. 2A illustrates a portion of a wire down determination system and method according to some embodiments.

FIG. 2B illustrates a portion of a wire down determination system and method according to some embodiments.

FIG. 2C illustrates a portion of a wire down determination system and method according to some embodiments.

FIG. 3 illustrates a system for operating a wire down system and method in accordance with some embodiments.

FIG. 4 illustrates a first scenario that includes a PV detection event that clears before a trap is sent according to some embodiments.

FIG. 5 shows a second scenario of a repeat trap, non-persistent clear according to some embodiments.

FIG. 6 depicts a third scenario that includes a partial voltage detection that does not meet persistent time according to some embodiments.

FIG. 7 depicts an example flowchart for a single-phase partial voltage alert state machine code analysis and execution according to some embodiments.

FIG. 8 shows the PVA events and trap mechanism for multiphase meters according to some embodiments.

FIG. 9 illustrates example PVA commands stored on one or more meter computers (e.g., NIC cards) according to some embodiments.

FIG. 10 depicts an example get status commands generated by the system according to some embodiments.

FIG. 11 depicts non-limiting examples of enable and configure parameter commands according to some embodiments.

FIG. 12 shows non-limiting examples of PVA CATT commands including enable and configure parameter commands according to some embodiments.

FIG. 13 illustrates non-limiting examples of PVA CATT commands including disable PVA commands according to some embodiments.

FIG. 14 shows an architecture diagram 200 of a system for operating a wire down system and method according to one embodiment.

### DETAILED DESCRIPTION

Before any embodiments are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The following discussion is presented to enable a person skilled in the art to make and use embodiments. Various modifications to the illustrated embodiments will be readily apparent to those skilled in the art, and the generic principles herein can be applied to other embodiments and applications without departing from embodiments. Thus, embodiments are not intended to be limited to embodiments shown, but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments. Skilled artisans will recognize the examples provided herein have many useful alternatives and fall within the scope of embodiments.

Some embodiments include methods for analysis of events and notifications generated by an electrical meter (e.g., such as a “smart” meter) during outages. In some embodiments, the system and methods include using data from smart electrical meter and system configurations to enhance distribution operator's ability to quickly identify hazardous energized wire down situations. In some embodiments, the method can enable rapid identification of primary distribution energized wire down locations. In some embodiments, the methods can use signals and retrieved operational states from one or more meters to interpret the actual energized state of meters involved in an outage. In some embodiments, any electrical meter described herein can be a voltage sensing device. In some embodiments, any of the embodiments described herein can utilized one or more voltage sensing devices.

In some embodiments, the electrical meters can be one or more advanced metering infrastructure meters. For example, some embodiments include AMI/SmartMeters™, although the methods described herein do not need to rely on the use of AMI/SmartMeters™. For example, some embodiments can use any device configured to be interrogated and/or provide information as described herein for AMI/SmartMeters™. In some embodiments, outage identification methods can be applied to any utility deploying AMI/SmartMeters™. Some embodiments can utilize AMI/SmartMeter™ feature enhancements that can improve the functionality of the product. In some further embodiments, data can be retrieved from other sources such as, but not limited to, individual line sensors and/or relays. In some further embodiments, the values of line sensors can include, but not be limited to, fault location, real time load for switching decisions, voltage, and verification of voltage present on one or all phases.

In some embodiments, by using one or more SmartMeters™, the type of outage can be predicted. Some embodiments can use data derived from or based on the state one or more SmartMeters™ to predict estimate the type of outage. For example, some embodiments include estimation or prediction of an energized wire down outage (e.g., an outage involving a down wire that is live and still carrying voltage and/or current). Other embodiments include estimation or prediction of an energized wire down outage involving a down wire that is not energized.

In some embodiments, the systems and methods described herein can determine the type and location of tap and fuse level outages to and/or within a transformer. In some embodiments, using a combination of specific traps and events, queries from the meter, and expert knowledge of electrical primary and secondary distribution infrastructure, specific events can be isolated to specific distribution equipment location. In some embodiments, any specific detected event can be categorized as energized or not energized. In some embodiments, the meter and/or the system and method can prioritize responses to hazard calls by indicating more or less likely actual problem locations.

In some embodiments, some meters (e.g., such as smart meters, including the aforementioned AMI/SmartMeters™can respond with data when the meter voltage is less than 50%. In some embodiments, although voltage cannot be queried, the meter can allow an operator to know when supplied voltage is either normal, partial, or de-energized (i.e., when there is no response). In some embodiments, this can indicate a back-feed condition which can include, but not be limited to, a broken wire, a burnt-out jumper, or a situation where only one fuse has operated on a two or three wire line. In some embodiments, arcing detection can be used to determine if there is an energized wire is down, however there is no way to differentiate between an open wire and an un-energized wire down. In some embodiments, arc detection can be possible with line sensors and substation relays.

Table 1 shows meter voltage summary information according to some embodiments:

TABLE 1
Smart meter voltage response

| Voltage or Voltage Range | AMI Meter | Importance |
|---|---|---|
| About 90% and above | Normal communications | Confirms meters |
| | and fully operational | are fully ener- |
| | meter | gized |
| About 75% to about 90% | Voltage sag | Possible high load |
| | | and/or overloaded |
| | | circuit |
| About 25% to 75% | Normal communications, | Confirms meters |
| | but meter stops | are in a back- |
| | operating | feed condition |
| Less than about 25% | Total loss of communica- | Implies meters |
| | tion | are fully de- |
| | | energized |

In reference to Table 1 showing meter voltage summary information, in some embodiments, a combination of inputs including, but not limited to, meter traps, waveform arcing and phase shift data, and/or meter ping and read responses can be used to determine a high impedance fault detection. For example, in one non-limiting embodiment, a voltage of about 90% of nominal and above can indicate normal operations and a fully functional meter, and can be used to confirm the meter is fully energized. Further, in some embodiments, a voltage range of between about 75% and 90% of nominal can indicate a voltage sag, and in some cases can be attributed to high load and/or an overloaded circuit. Further, in some embodiments, a voltage range of between 25% and 75% can be indicative of normal communications, but the meter has stop operating, and/or can indicate meters are in a back-feed condition. Further, in some embodiments, a voltage of less than about 25% of nominal can indicate a total loss of communication, and can imply meters are fully de-energized.

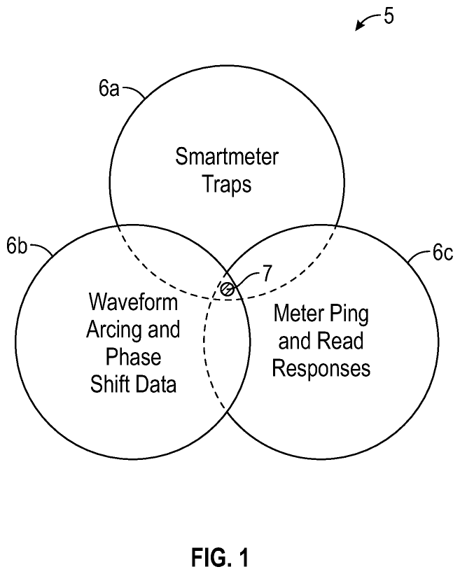

FIG. 1 illustrates a high impedance fault implementation 5 according to some embodiments. In some embodiments, the highest certainty can be obtained from an intersection (shown as the central data overlap marked as 7) of information/data comprising overlapping data circles including smart meter trap data 6a, waveform arcing and phase shift data 6b, and meter ping and read responses data 6c as illustrated in FIG. 1. In some embodiments, a combination of ping and read responses coupled with behaviors at different voltage levels can enable the determination of the nature of the broken wire condition.

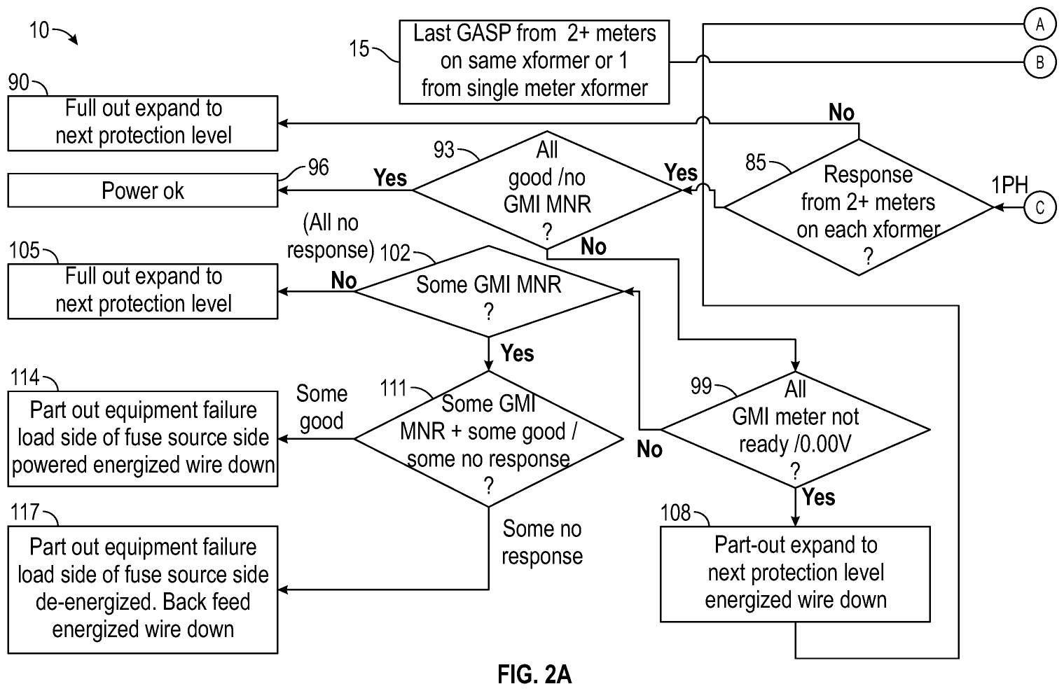

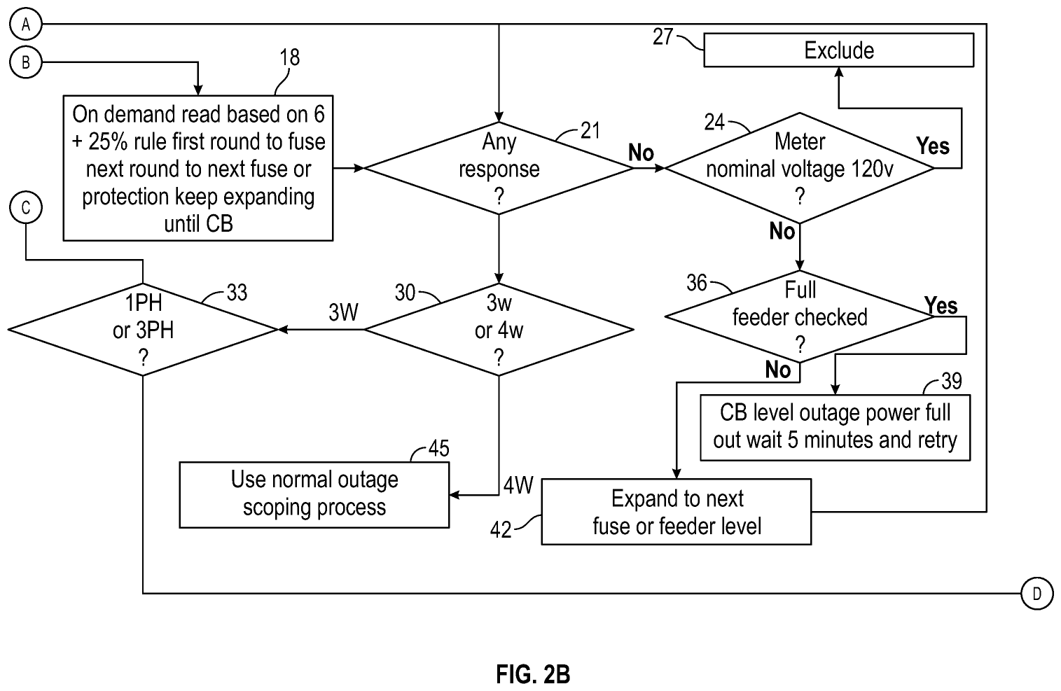

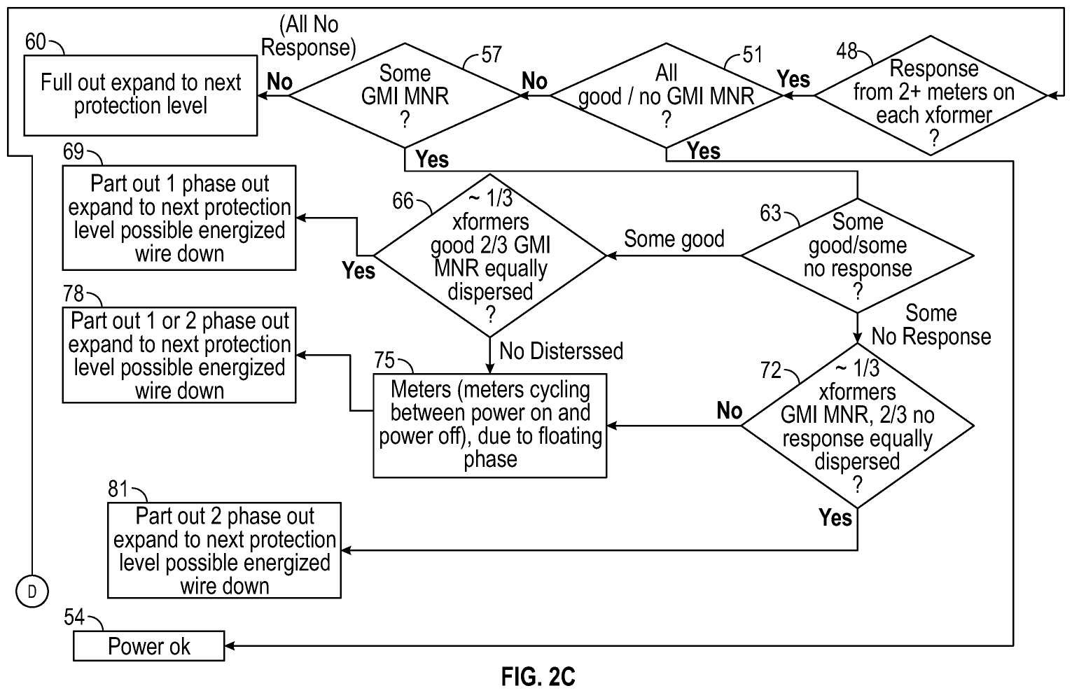

FIGS. 2A-2C illustrates a wire down determination system and method 10 according to some embodiments. For example, FIG. 2A a portion of the wire down determination system and method 10 according to some embodiments, and FIG. 2B another portion of the wire down determination system and method 10 according to some embodiments. Further, FIG. 2C includes a final portion of the wire down determination system and method 10 according to some embodiments. Referring initially to FIG. 2A, step 15 includes a “last gasp from two or more meters on the same transformer and/or a last gasp from one meter on a single meter transfer”. In this example embodiments, step 15 includes an embodiments where a last signal can be received from two or more meters on the same transformer. Further, step 15 includes an embodiments where a last signal can be received from a last gasp from one meter on a single meter transformer.

In some embodiments, the wire down determination system and method can use inbound last gasp messages from the meter (e.g., a real-time outage alert trap) to assess outage extent. In some embodiments, at a specific minimum threshold, outage identification can be initiated. For example, in some embodiments, initial traps can generally begin at about 25% to 50% of voltage. In some embodiments, when traps from more than two meters on a transformer are received, an outage initiation process can begin by probing or reading a sample of meters coupled to the transformer. In some embodiments, the sample rate can be based on a formula that can be adjusted to define a level of confidence. For example, in the case where there are 20 meters, 11 meters are probed. Further, for example, referring to FIG. 2B, in some embodiments, step 18 includes “on demand read based on a six plus 25% rule. In this instance, data reads can include data from six meters plus 25% of the total number of meters on an identified transformer.

In some embodiments, outage scoping is started on a small scale, and then expanded to determine extent. In some embodiments, outages can be contained by protective devices such as fuses, and/or dynamic protection (re-closers, and/or sectionalizers). In this instance, probing can start on a section of circuit that has reported last gasps, and can check all of the transformers that are protected by the first upstream fuse in the feeder. In some embodiments, if it is determined that all of the meters in that investigation are in the same outage state (hence all on the same side of the circuit outage), probing can continue to the next upstream protective device on that feeder. In some embodiments, this process can continue until the whole feeder has been checked.

In some embodiments, the wire down determination system and method can sample the meter state. In some embodiments, the wire down determination system and method can request an on-demand read (e.g., a real time or nearly real time request for meter kWh usage and voltage) on a sampling basis, and using the total number of meters sample per transformer base on six meters, with minimum pulls of 25% of the total transformer meter count. In some embodiments, this sampling ratio can be used on each transformer scoped in the outage at each protection level. In some embodiments, step 21 can include “any response” where the wire down determination system and method can determine if there is any response from any of the sampled meters. In some embodiments, if there is no response from step 21, the wire down determination system and method can proceed with step 24 including a check “meter nominal voltage 120V”, where the wire down determination system and method can determines if any of the sample meters are 120 VAC nominal (e.g., versus 240, 277V, or other nominal voltage). In some embodiments, these meters can have a different partout threshold.

In some embodiments, if there is a response, step 27 can include an “exclude” function, where the wire down determination system and method can exclude any meters that have 120V nominal voltages. Further, in some embodiments, if there is a response, the wire down determination system and method can proceed to a check step 30 that includes “3 W or 4 W”, for three or four wire to the meter, with the feeder type 3 wire (no common neutral) or 4 wire (3-phase with common neutral).

In some embodiments, for a three wire system, check step 33 can include “1 Ph or 3 Ph” check for one phase or three phase power delivery, where the wire down determination system and method can determine if the feeder comprises a single phase tap or three phases. In some embodiments, for a four wire system, step 45 “use normal outage scoping process” can proceed with a recommendation for a normal outage scoping process where the wire down detection is not functional on four wire feeders.

In some embodiments, if there is a negative response to step 24, step 36 can include a “full feeder checked”, where the wire down determination system and method can determine if the full feeder has been checked for outage. In some embodiments, for a positive response, the wire down determination system and method can proceed with step 39 “CB (circuit breaker) level outage power full out wait five minutes and re-entry” when there appears to be a full feeder outage. In some embodiments, the wire down determination system and method can wait five minutes to see if the circuit breaker resets, and can wait for the advanced metering infrastructure (AMI) mesh network to reform. In some embodiments, for a negative response, in step 42 “expand to next fuse or feeder level”, the wire down determination system and method can determine if the full feeder has not been checked, and can continue to check for meter outage states in order to pinpoint outage and/or wire down location.

Referring to FIG. 2C, in some embodiments, the wire down determination system and method can proceed with step 48 that includes “response from two or more meters on each transformer”. In this instance, with a minimum of two or more responses from interrogated meters per transformer, the wire down determination system and method can proceed with step 51 that includes “all good or not GMI MNR”, where all meters respond back with full power on responses, and no meters in a part out state, which if positive, the wire down determination system and method can proceed with step 54 that includes “power ok”. In this instance, the wire down determination system and method has determined that power is confirmed, and there is no outage at this protection point. In some other embodiments, if the wire down determination system and method determines that the answer to step 51 is negative, step 57 includes a test for “some GMI MNR”, where the wire down determination system and method can determine if there is GMI MNR (and some good/no outage) indicating a mix of part out and no outage. GMI MNR is an on demand read respond indicating that the network interface card (NIC) is on, meter is off which indicates the meter is in a part out state. Further, GMI MNR equates to GMI meter not ready, which equates to the read response where a smart meter NIC is energized but the meter metrology board is not. This is the state indicating a part out, and generally occurs when voltage is between about 25% and 75%.

In some embodiments, if the wire down determination system and method determines the answer is negative, step 60 includes a “full out expand to next protection level”. In this case, if it is determined that the initial protection outage level is in a full out state, the wire down determination system and method can continue to the next protection level (e.g., including, but not limited to fuse, dynamic protection, and substation circuit breaker evaluations). In some other embodiments, if the answer is positive, step 63 includes “some good or some no response”, where the wire down determination system and method can determine if the mixture of meters is good (i.e., no outage), and/or if the meters show no response (full out) with GMI MNR (part out).

In some embodiments, if the wire down determination system and method determines there are some good meters, step 66 can include a “about a third transformers good two thirds GMI MNR equally dispersed” test, where the wire down determination system and method can determine the mix of meters with no outage and meters that are at least partly out. In some embodiments, a positive response includes step 69 that includes “part out 1 phase out expand to next protection level, possible energized wire down”, with a determination of possible energized wire down, one phase out.

In some other embodiments, for a determination showing some or no response of step 63 includes “some good or some no response”, where the wire down determination system and method can determine if the mixture of meters is good (i.e., no outage), and/or if the meters show no response (full out) with GMI MNR (part out), step 72 includes a determination of “about one third transformers GMI MNR, two thirds no response equally dispersed”, where the wire down determination system and method can determine the mix of meters being full out and part out. In some embodiments, for a negative response, step 72 can determine step 75 “meters cycling between on and off due to a “floating phase” where for instances with floating phase, meters can cycle on off with change in customer loading. Further, in some embodiments, in step 78 that includes “part out one or two phase out, expand to next protection level possible energized wire down”, the wire down determination system and method can determine if a possible energized wire down condition includes one or two phases out, and the analysis can expand to the next level to determine the extent of outage. Further, in some embodiments, for a positive response, step 72 can lead to step 81 which includes “part out two phase out expand to next protection level possible energized wire down”, where the wire down determination system and method can determine a possible energized wire down with two phase down, and can expand analysis to the next level to determine the extent of the outage.

In some embodiments, for a three wire system, in the step 33, if the wire down determination system and method determines the feeder is a single phase tap, the wire down determination system and method (in step 85 of FIG. 2A) can make a determination “response from two plus meters on each transformer”, where an assessment is made if there are a minimum of two or more responses from interrogated meters. In some embodiments, for a negative response, the wire down determination system and method can proceed to step 90 that includes “full out expand to next protection level”, where it is determined that the initial protection outage level is in a full out state, and analysis can continue to the next protection level (fuse, dynamic protection, and/or substation circuit breaker).

In some embodiments, for a positive response to step 85, the wire down determination system and method can proceed with step 93 that includes “all good or no GMI MNR”, to determine if all meters respond back with full power on responses, with no meters in a part out state. For a positive response, step 96 includes “power ok”, providing a conclusion that there is no power outage.

In some embodiments, for a negative response, the wire down determination system and method can include a step 99 that includes “all GMI meter not ready/0.00V”, with a determination if all meters respond back with GMI MNR and 0.00V for voltage level. In some embodiments, with a negative response to step 99, the wire down determination system and method can include step 102 that includes “some GMI MNR” to determine if some GMI MNR (and some good/no outage) indicating a mix of part out and no outage, where for all no response (i.e., it is determined that the initial protection outage level is in a full out state), the wire down determination system and method can proceed to step 105 that includes “full out expand to next protection level”. In this instance, analysis can continue to the next protection level (fuse, dynamic protection, and/or substation circuit breaker). In some embodiments, for a positive response to step 99, step 108 includes “part out expand to next protection level energized wire down”, where the wire down determination system and method has determined that the section of feeder is part out, and the wire down determination system and method can expand to next protection level (fuse, dynamic protection, and/or substation circuit breaker). For example, see the decision flow in FIG. 2B to steps 18 and 42.

In some embodiments, for a positive response to step 102, the wire down determination system and method can proceed with step 111 that includes “some GMI MNR plus some good/some no response” to determine the mix of GMI MNR and power OK, full out. In this instance, the step 111 can be used to determine location of down wire. In some instances, this can occur at a level above the transformer (i.e., meters on transformer will have same response but differences from meters on different transformers indicating a state change between locations). Further, with some good responses, the wire down determination system and method can proceed to step 114 that includes “part out equipment failure load side of fuse source side powered energized wire down”, where the location of down wire is determined and wire down condition is determined as energized. Further, in some other embodiments, for a response of some no response, the wire down determination system and method can proceed with step 117 that includes “part out equipment failure load side of fuse source side de-energized back feed energized wire down”, where the location of down wire is determined, and wire down condition is determined as energized back feed.

Some embodiments include a multiphase meter anomaly detection (MMAD) system. In some embodiments, the MMAD system includes using one or more meter's internal anomaly detection alert as a notification of an abnormal condition. In some embodiments, the abnormal condition is a loss of one or more phases. In some embodiments, the MMAD is configured to send an alert when a loss of one phase is detected even if one or more other phases are still energized. In some embodiments, the MMAD system is able to detect a wire down condition in both 3 wire (3 phases, no neutral) and 4 wire (3 phases plus neutral) wire distribution systems. In some embodiments, by using one or more alerting methods from one or more smart meters, it is possible to detect where there is a 1 of 2, or 1 or 2 of 3 broken conductors on an electric distribution circuit. In some embodiments, discovery signals from 3 phase meters indicates that one of the phases has lost voltage is used to further detect partial out circuits on both 3 wire and 4 wire distribution circuits.

In some embodiments, the MMAD system includes the use of traps to aid in determine exactly which of one or more phases in a multi-phase smart meter is experiencing an abnormal condition (e.g., a loss of power) as well as pinpointing the source of the anomaly. In embodiments, a trap includes a (near) real-time alert sent by a meter and/or meter NIC. The extensive number of smart meters within an electrical grid forms a data management network that is so large that continued querying of all the smart meters' conditions becomes a burden on both computer and network resources. To solve this problem, as well as the previously unsolved problem of not being able to determine exactly which phase and/or how many phases are experience issues, one or more traps are saved on each of one or more smart meter's NICs and are configured with traps that send unsolicited messages automatically when abnormal conditions are detected according to some embodiments.

In some embodiments, the MMAD system includes a partial voltage (PV) alert. In some embodiments, a partial voltage alert is the ability to detect voltage fluctuations/outages occurring at input phase(s) and ability to report such input voltage fluctuations to UIQ in the form of traps. In some embodiments, this feature is implemented in two distinct phases as per different meter/NIC specific voltage detection mechanisms. In some embodiments, a phase 1 approach includes the meter detecting a PV condition and notifying the network interface card (NIC) via Power Fail (PF) pin, where the focus is AX (single phase). In some embodiments, a phase 2 approach includes the meter detects a partial voltage condition and generates a low loss potential flag which the NIC is configured to check, where the NIC monitors input phase voltages.

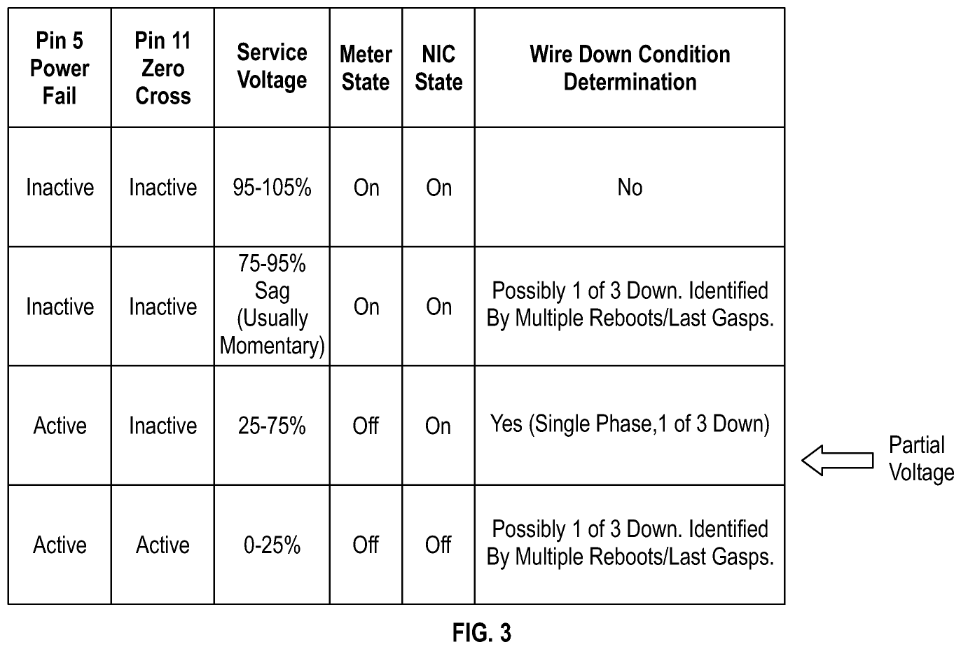

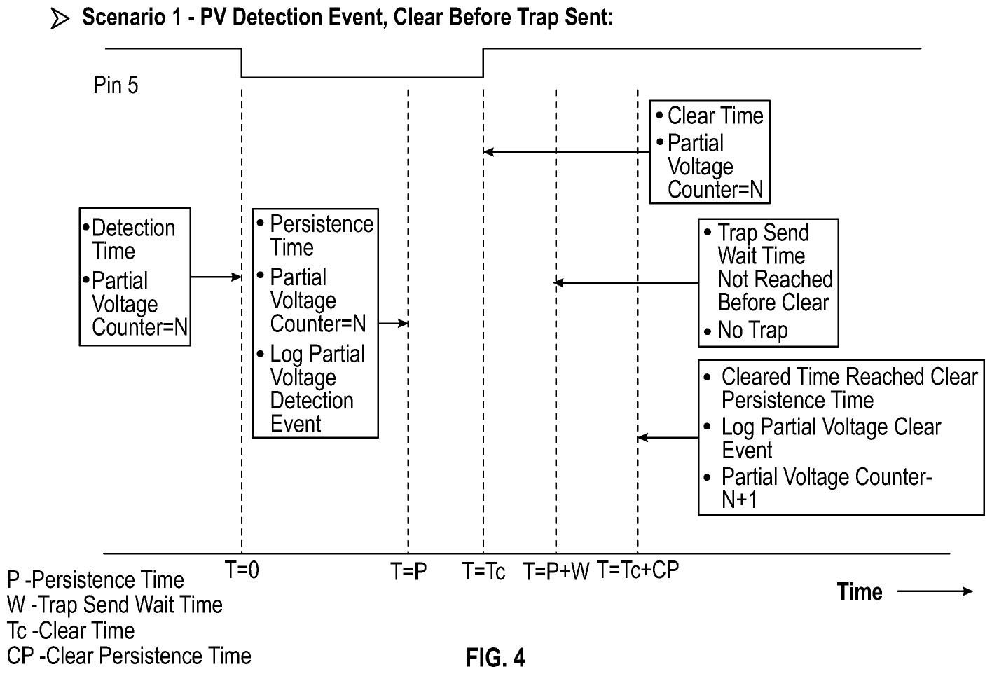

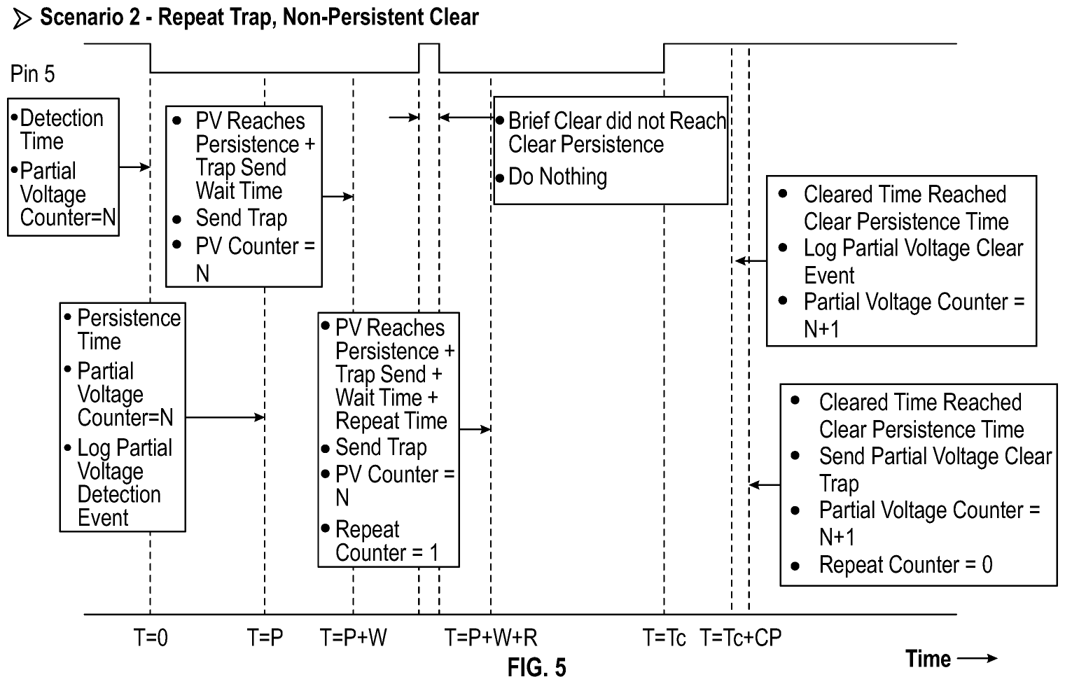

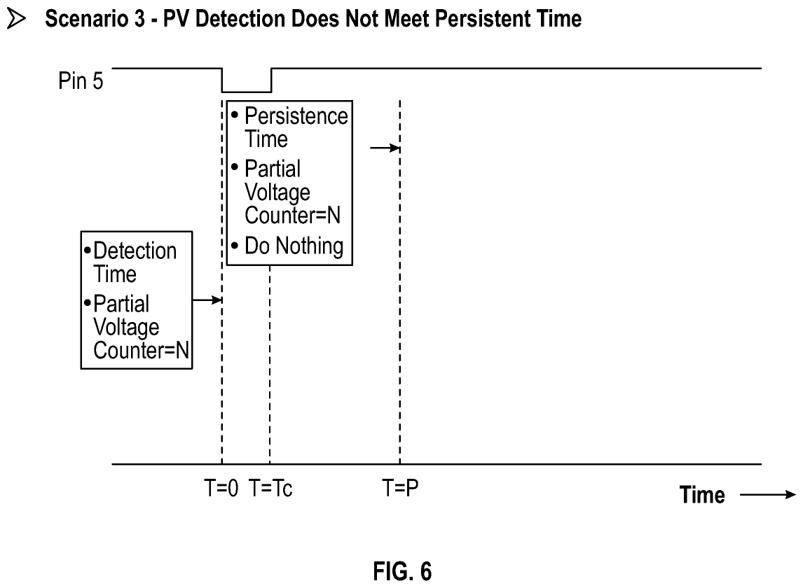

In some embodiments, the MMAD system includes a single-phase partial voltage detection function. In some embodiments, the function includes new traps/events driven by a pin 5 (i.e., PF pin) activation status that includes: (1) partial voltage detection trap; (2) partial voltage clear trap; (3) partial voltage detection event; and (4) partial voltage clear event. FIG. 3 illustrates the pin 5 active/inactive and pin 11 (Zero Cross) inactive condition that triggers an alert that a single phase, 1 of 3 down, condition has occurred. FIG. 4 illustrates a first scenario that includes a PV detection event that clears before a trap is sent according to some embodiments. FIG. 5 shows a second scenario of a repeat trap, non-persistent clear according to some embodiments. FIG. 6 depicts a third scenario that includes a partial voltage detection that does not meet persistent time according to some embodiments. {{PG&E: Can we get a little more information on what each pin does?? Are they directly connected to a phase?? Are they connected to a sensor?? Are there example of what other pins do on the circuit board?? It says the pins become active, is this an energized signal and if so what is providing the signal??}}

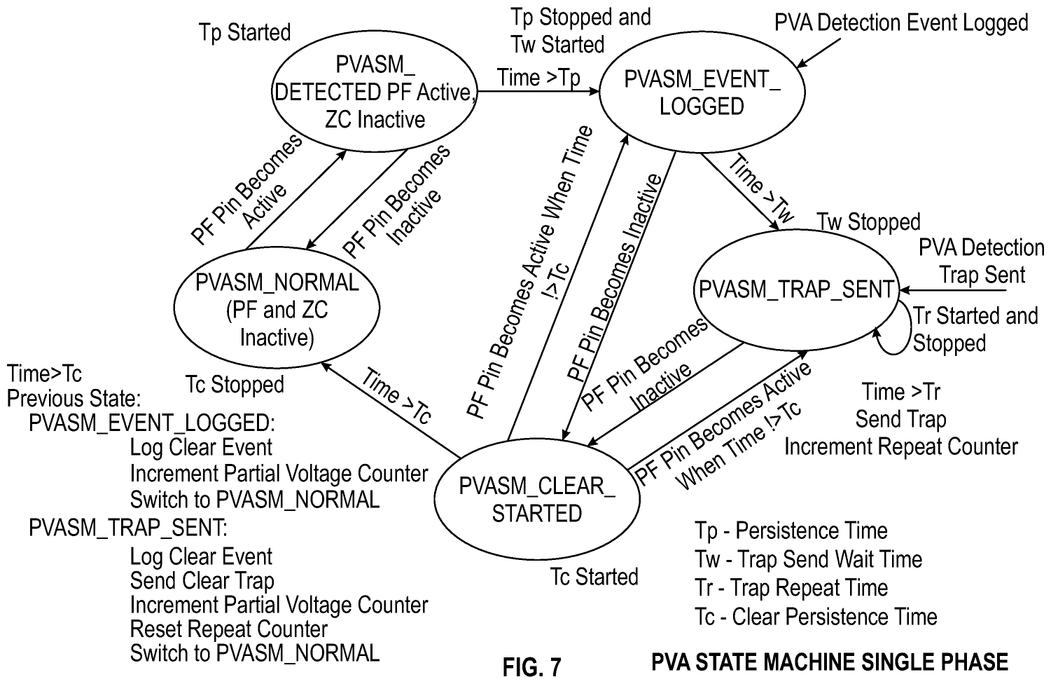

In some embodiments, partial voltage detection for single phase meters is executed by periodic monitoring of PFAIL signal (Pin 5) at an interval (e.g., 1 second). In some embodiments, the system is configured to enable and/or configure trap parameters, and get statuses using one or more over the air commands. In some embodiments, configuring trap parameters includes configuring one or more of: persistence time, clear time, trap wait time, and/or repeat time. In some embodiments, PVA events are logged to NIC's persistence memory (flash) and alarms are reported via traps. FIG. 7 depicts an example flowchart for a single-phase partial voltage alert state machine code analysis and execution according to some embodiments.

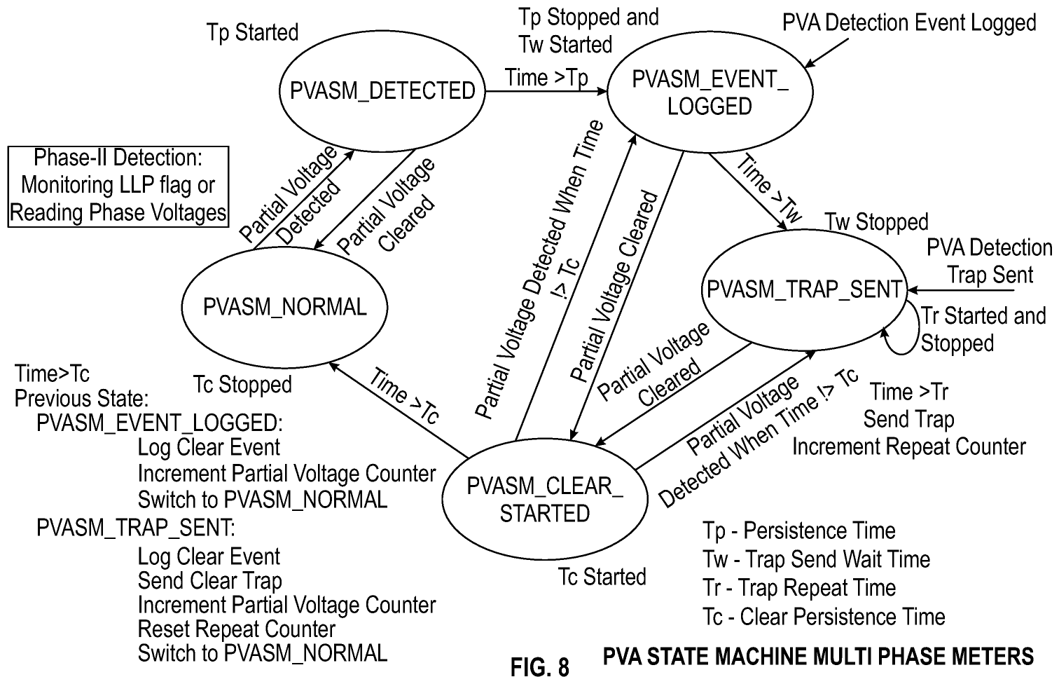

In some embodiments, a partial voltage detection for polyphase phase meters is performed by periodic monitoring at an interval (e.g., 60 seconds). In some embodiments, as in Aclara Meters for example, the system includes monitoring for a low loss potential (LLP) flag and triggering a PVA state machine code analysis and execution when LLP condition is found. In some embodiments, as in L+G Focus Meters for example, the system includes monitoring by reading voltage of all three phases and comparing if anyone gets lowered by “voltage threshold” of nominal service voltage. In some embodiments, new configurable parameters are introduced in an existing PVA single phase command that includes meter phase and voltage threshold. In some embodiments, the PVA events and trap mechanism for multiphase meters is same as single phase meters. The PVA events and trap mechanism for multiphase meters is shown in FIG. 8 according to some embodiments.

In some embodiments, 3 phase SmartMeters are powered by a Phase A-to-Neutral or Phase A-B Line-to-Line. In some embodiments, a low loss potential event is created when phase A or B or C is reduced a predetermined amount (e.g., approximately 83 Volts), or when both phases B and C are reduced a predetermined amount (e.g., approximately 118 Volts). In some embodiments, the system is configured to enable the network interface card (NIC) to become aware of the low loss potential condition upon the next read of data from internal metrology and/or a queried metrology from a remote command center. In some embodiments, there are 3 different traps for 3 or 4 phase meters: Low Loss Potential Detection Trap, Low Loss Potential Detection Repeat Trap, and Low Loss Potential Clear Trap.

In some embodiments, a Low Loss Potential Detection Trap includes one or more of: a Low Loss Potential Event Counter (initially=0), a Low Loss Potential Event Detection Time, and a configurable Low Loss Potential Persistence Time (N=1 to 10 minutes). In some embodiments, a Low Loss Potential Detection Trap includes execution of one or more of the 5 following steps: (1) NIC reading the following registers via metrology at predetermined intervals (e.g., 60 seconds): (a) stat Standard Table 3, Offset 1, Length 2; (b) Normal=00 00; (c) Low Loss Potential=00 02; (d) Va=MT72, Offset 14, Length 2; (e) Vb=MT72, Offset 18, Length 2; (f) Vc=MT72, Offset 22, Length 2; (2) when Low Loss Potential Condition is found, Capture LLP Event Detection Time; (3) continue to read from metrology every 60 seconds. (4) if low loss potential condition has cleared before reaching Low Loss Potential Persistence Time, do nothing. (5) When Low Loss Potential Condition has persisted to Low Loss Potential Persistence Time (N minutes), send LLP Trap with the following payload: (a) Low Loss Potential Detection Time; (b) Low Loss Potential Duration; (c) Voltages (Va, Vb, Vc); (d) Low Loss Potential Event Counter; (e) Boot Counter.

In some embodiments, a Low Loss Potential Detection Repeat Trap includes one or more of: a Configurable Repeat Time Setting (R=1 to 60 Minutes), and a Repeat Trap Sent every R Minutes since last Trap. In some embodiments, a Low Loss Potential Detection Trap includes execution of one or more of the 2 following steps: (1) continue to read metrology every 60 seconds; (2) when Low Loss Potential event duration reaches Low Loss Potential Trap repeat time R since the prior trap was sent, send Low Loss Potential Trap with following payload: (a) Low Loss Potential Detection Time; (b) Low Loss Potential Duration; (c) Voltages (Va, Vb, Vc); (d) Low Loss Potential Event Counter; (e) Boot Counter.

In some embodiments, a Low Loss Potential Clear Trap includes a configurable Low Loss Potential Clear Time Setting (e.g., C=0 to 5 Minutes). In some embodiments, a Low Loss Potential Clear Trap includes execution of one or more of the 5 following steps: (1) continue to read metrology every 60 seconds; (2) when Low Loss Potential flag has cleared (00 00), start Low Loss Potential; (3) clear timer; (4) continue to read metrology every 60 Seconds; (5) when Low Loss Potential has remained cleared to LLP Clear Time (C), increment LLP Event Counter send Low Loss Potential Clear Trap with the following payload: (a) Low Loss Potential Detection Time; (b) Low Loss Potential Duration Voltages (Va, Vb, Vc); (c) Low Loss Potential Event Counter; (d) Boot Counter Plans for LLP Trap.

In some embodiments, unlike PV traps where metrology is off, the 3 phase smart meters (SMs) can provide voltage readings down to low levels when non-power supply phases have LLP. In some embodiments, the system is configured to display each trap and an associated transformer in a DMS Map along with the Va, Vb, Vc. In some embodiments, they system includes associated LLP SM counts in OMT outage summary to alert potential hazard.

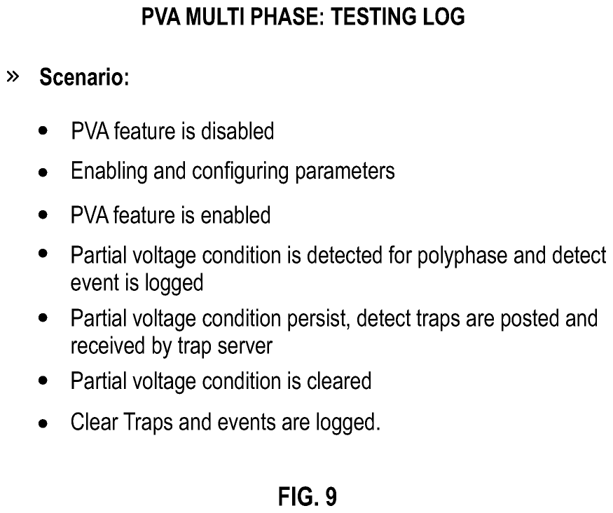

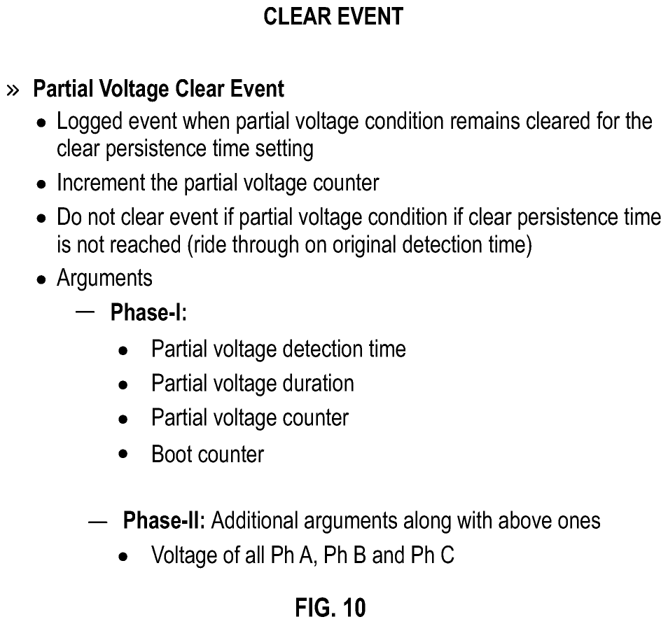

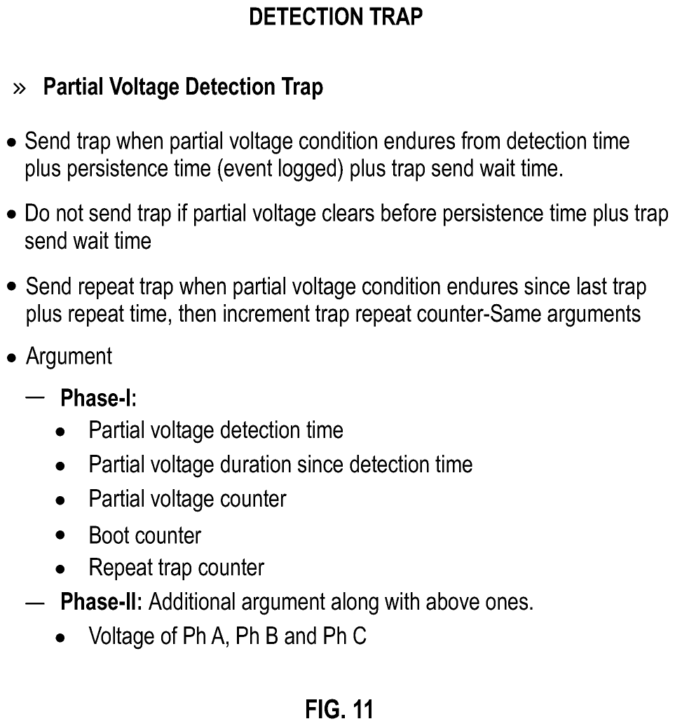

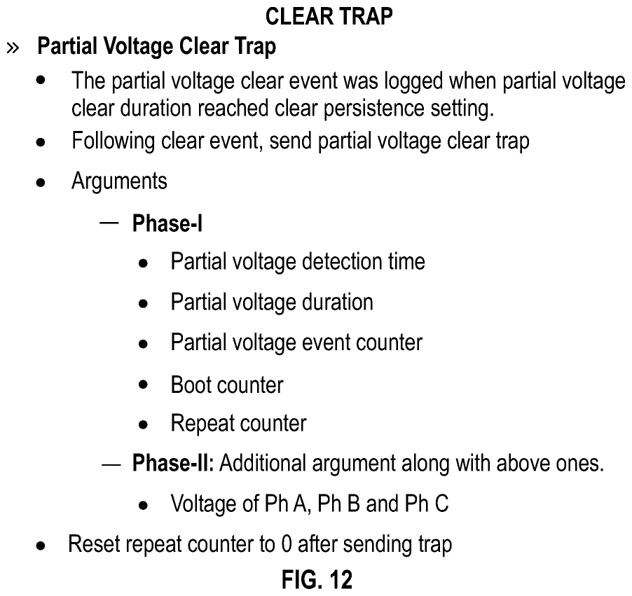

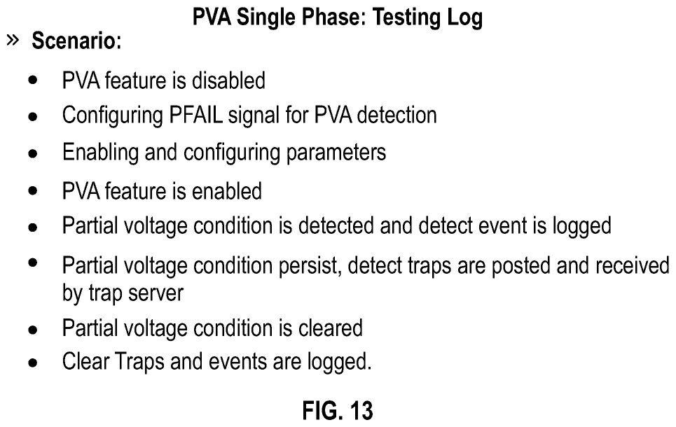

FIG. 9 illustrates example PVA commands stored on one or more meter computers (e.g., NIC cards) according to some embodiments. FIG. 10 depicts an example get status commands generated by the system according to some embodiments. FIG. 11 depicts non-limiting examples of enable and configure parameter commands according to some embodiments. FIG. 12 shows non-limiting examples of PVA Communications Access Test Tool (CATT) commands including enable and configure parameter commands according to some embodiments. In some embodiments, CATT includes an interface tool to read and convert data and information from NIC cards. FIG. 13 illustrates non-limiting examples of PVA CATT commands including disable PVA commands according to some embodiments.

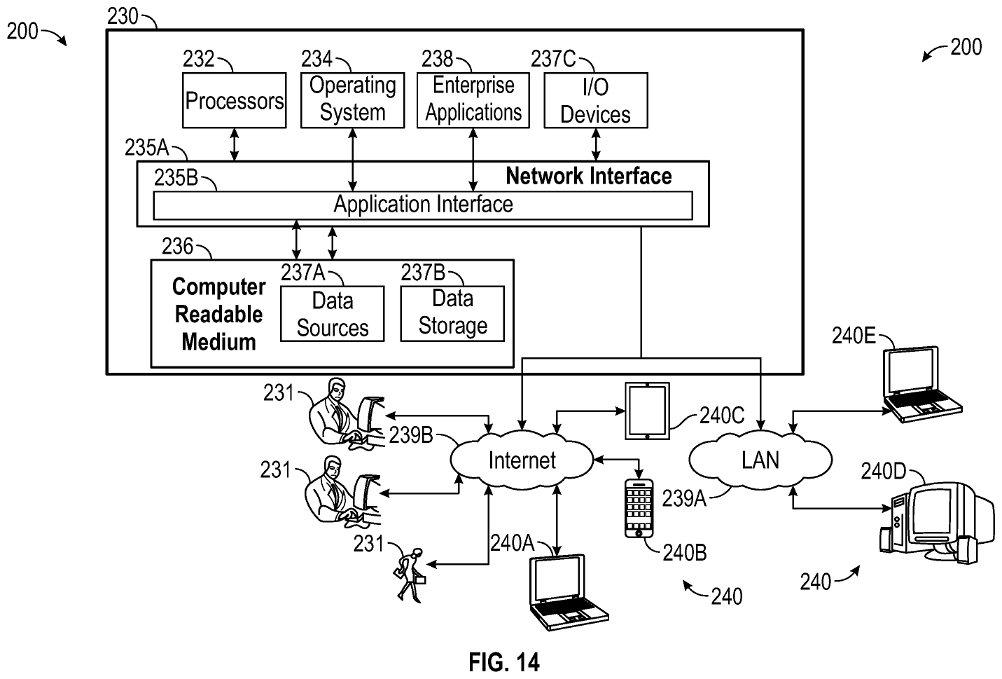

In some embodiments, any of the meters, systems, or assemblies of a wire down system and method described herein can use at least one computing system within a networked metering or power network. For example, FIG. 14 shows an architecture diagram 200 of a system for operating a wire down system and method according to one embodiment. The diagram 200 shows one example of a system 230 for performing one or more of the methods of the wire down system that, as one non-limited example, can operate, read, send data and/or read data from one or more meters (e.g., such as smart meters described earlier). As shown, the system 230 can include at least one computing device, including one or more processors. Some processors can include processors 232 residing in one or more conventional server platforms. In some embodiments, the system 230 can include a network interface 235a and/or an application interface 235b coupled to at least one processor 232 capable of running at least one operating system 234, and one or more of the software modules 238 (e.g., such as enterprise applications). In some embodiments, the software modules 238 can include server-based software platform that can include wire down system and method software modules suitable for hosting at least one user account and at least one client account, as well as transferring data between one or more accounts.

Some embodiments relate to or include a device or an apparatus for performing these operations of the operating system 234 and/or the software modules 238. The apparatus can be specially constructed for the required purpose, such as a special purpose computer. In some embodiments, when defined as a special purpose computer, the computer can also perform other processing, program execution or routines that are not part of the special purpose, while still being capable of operating for the special purpose. Alternatively, in other embodiments, the operations can be processed by a general purpose computer selectively activated or configured by one or more computer programs stored in the computer memory, cache, or obtained over a network. In some embodiments, when data are obtained over a network, the data can be processed by other computers on the network, e.g. a cloud of computing resources.

With the above embodiments in mind, it should be understood that the invention can employ various computer-implemented operations involving wire down system and method data stored in computer systems. Moreover, in some embodiments, the above-described databases and models throughout the wire down system and method can store analytical models and other data on computer-readable storage media within the system 230 and on computer-readable storage media coupled to the system 230. In addition, in some embodiments, the above-described applications of the wire down system and method system can be stored on computer-readable storage media within the system 230 and on computer-readable storage media coupled to the system 230. These operations are those requiring physical manipulation of physical quantities. Usually, though not necessarily, these quantities take the form of electrical, electromagnetic, or magnetic signals, optical or magneto-optical form capable of being stored, transferred, combined, compared and otherwise manipulated.

Some embodiments include the system 230 comprising at least one computer readable medium 236 coupled to at least one data storage device 237b, and/or at least one data source 237a, and/or at least one input/output device 237c. In some embodiments, the invention embodied by the wire down system and method can be embodied as computer readable code on a computer readable medium 236. In some embodiments, the computer readable medium 236 can be any data storage device that can store data, which can thereafter be read by a computer system (such as the system 230). Examples of the computer readable medium 236 can include hard drives, network attached storage (NAS), read-only memory, random-access memory, FLASH based memory, CD-ROMs, CD-Rs, CD-RWs, DVDs, magnetic tapes, other optical and non-optical data storage devices, or any other physical or material medium which can be used to tangibly store the desired information or data or instructions and which can be accessed by a computer or processor (including processors 232).

In some embodiments, the computer readable medium 236 can also be distributed over a conventional computer network via the network interface 235a so that the wire down system and method embodied by the computer readable code can be stored and executed in a distributed fashion. For example, in some embodiments, one or more components of the system 230 can be tethered to send and/or receive data through a local area network (“LAN”) 239a. In some further embodiments, one or more components of the system 230 can be tethered to send or receive data through an internet 239b (e.g., a wireless internet). In some embodiments, at least one software application 238 running on one or more processors 232 can be configured to be coupled for communication over a network 239a, 239b. In some embodiments, one or more components of the network 239a, 239b can include one or more resources for data storage, including any other form of computer readable media beyond the media 236 for storing information and including any form of computer readable media for communicating information from one electronic device to another electronic device.

In some embodiments, the network 239a, 239b can include wide area networks (“WAN”), direct connections (e.g., through a universal serial bus port) or other forms of computer-readable media 236, or any combination thereof. Further, in some embodiments, one or more components of the network 239a, 239b can include a number of client devices which can be personal computers 240 including for example desktop computers 240d, laptop computers 240a, 240e, digital assistants and/or personal digital assistants (shown as 240c), cellular phones or mobile phones or smart phones (shown as 240b), pagers, digital tablets, internet appliances, and other processor-based devices. In general, a client device can be any type of external or internal devices such as a mouse, a CD-ROM, DVD, a keyboard, a display, or other input or output devices 237c. In some embodiments, various other forms of computer-readable media 236 can transmit or carry instructions to a computer 240, including a router, private or public network, or other transmission device or channel, both wired and wireless. In some embodiments, the software modules 238 can be configured to send and receive data from a database (e.g., from a computer readable medium 236 including data sources 237a and data storage 237b that can comprise a database), and data can be received by the software modules 238 from at least one other source. In some embodiments, at least one of the software modules 238 can be configured within the system to output data to a user 231 via at least one smart meter (e.g., to a computer 240 comprising a smart meter).

In some embodiments, the system 230 as described above can enable one or more users 231 to receive, analyze, input, modify, create and send data to and from the system 230, including to and from one or more enterprise applications 238 running on the system 230. Some embodiments include at least one user 231 coupled to a computer 240 accessing one or more modules of the wire down system and method including at least one enterprise applications 238 via a stationary I/O device 237c through a LAN 239a. In some other embodiments, the system 230 can enable at least one user 231 (through computer 240) accessing enterprise applications 238 via a stationary or mobile I/O device 237c through an internet 239a.

The subject matter described herein are directed to technological improvements to the field of electrical power distribution systems by using smart meter internal anomaly monitoring to identify the location of a loss of power outside the smart meter. The disclosure describes the specifics of how a machine including one or more computers comprising one or more processors and one or more non-transitory computer readable media implement the system and its improvements over the prior art. The instructions executed by the machine cannot be performed in the human mind or derived by a human using a pen and paper but require the machine to convert process input data to useful output data. Moreover, the claims presented herein do not attempt to tie-up a judicial exception with known conventional steps implemented by a general-purpose computer; nor do they attempt to tie-up a judicial exception by simply linking it to a technological field. Indeed, the systems and methods described herein were unknown and/or not present in the public domain at the time of filing, and they provide technologic improvements advantages not known in the prior art. Furthermore, the system includes unconventional steps that confine the claim to a useful application.

It is understood that the system is not limited in its application to the details of construction and the arrangement of components set forth in the previous description or illustrated in the drawings. The system and methods disclosed herein fall within the scope of numerous embodiments. The previous discussion is presented to enable a person skilled in the art to make and use embodiments of the system. Any portion of the structures and/or principles included in some embodiments can be applied to any and/or all embodiments: it is understood that features from some embodiments presented herein are combinable with other features according to some other embodiments. Thus, some embodiments of the system are not intended to be limited to what is illustrated but are to be accorded the widest scope consistent with all principles and features disclosed herein.

Some embodiments of the system are presented with specific values and/or setpoints. These values and setpoints are not intended to be limiting and are merely examples of a higher configuration versus a lower configuration and are intended as an aid for those of ordinary skill to make and use the system.

Any text in the drawings are part of the system's disclosure and is understood to be readily incorporable into any description of the metes and bounds of the system. Any functional language in the drawings is a reference to the system being configured to perform the recited function, and structures shown or described in the drawings are to be considered as the system comprising the structures recited therein. Any figure depicting a content for display on a graphical user interface is a disclosure of the system configured to generate the graphical user interface and configured to display the contents of the graphical user interface. It is understood that defining the metes and bounds of the system using a description of images in the drawing does not need a corresponding text description in the written specification to fall with the scope of the disclosure.

Furthermore, acting as Applicant's own lexicographer, Applicant imparts the explicit meaning and/or disavow of claim scope to the following terms:

Applicant defines any use of “and/or” such as, for example, “A and/or B,” or “at least one of A and/or B” to mean element A alone, element B alone, or elements A and B together. In addition, a recitation of “at least one of A, B, and C,” a recitation of “at least one of A, B, or C,” or a recitation of “at least one of A, B, or C or any combination thereof” are each defined to mean element A alone, element B alone, element C alone, or any combination of elements A, B and C, such as AB, AC, BC, or ABC, for example.

“Substantially” and “approximately” when used in conjunction with a value encompass a difference of 5% or less of the same unit and/or scale of that being measured.

“Simultaneously” as used herein includes lag and/or latency times associated with a conventional and/or proprietary computer, such as processors and/or networks described herein attempting to process multiple types of data at the same time. “Simultaneously” also includes the time it takes for digital signals to transfer from one physical location to another, be it over a wireless and/or wired network, and/or within processor circuitry.

As used herein, “can” or “may” or derivations there of (e.g., the system display can show X) are used for descriptive purposes only and is understood to be synonymous and/or interchangeable with “configured to” (e.g., the computer is configured to execute instructions X) when defining the metes and bounds of the system. The phrase “configured to” also denotes the step of configuring a structure or computer to execute a function in some embodiments.

In addition, the term “configured to” means that the limitations recited in the specification and/or the claims must be arranged in such a way to perform the recited function: “configured to” excludes structures in the art that are “capable of” being modified to perform the recited function but the disclosures associated with the art have no explicit teachings to do so. For example, a recitation of a “container configured to receive a fluid from structure X at an upper portion and deliver fluid from a lower portion to structure Y” is limited to systems where structure X, structure Y, and the container are all disclosed as arranged to perform the recited function. The recitation “configured to” excludes elements that may be “capable of” performing the recited function simply by virtue of their construction but associated disclosures (or lack thereof) provide no teachings to make such a modification to meet the functional limitations between all structures recited. Another example is “a computer system configured to or programmed to execute a series of instructions X, Y, and Z.” In this example, the instructions must be present on a non-transitory computer readable medium such that the computer system is “configured to” and/or “programmed to” execute the recited instructions: “configure to” and/or “programmed to” excludes art teaching computer systems with non-transitory computer readable media merely “capable of” having the recited instructions stored thereon but have no teachings of the instructions X, Y, and Z programmed and stored thereon. The recitation “configured to” can also be interpreted as synonymous with operatively connected when used in conjunction with physical structures.

It is understood that the phraseology and terminology used herein is for description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The previous detailed description is to be read with reference to the figures, in which like elements in different figures have like reference numerals. The figures, which are not necessarily to scale, depict some embodiments and are not intended to limit the scope of embodiments of the system.

Any of the operations described herein that form part of the invention are useful machine operations. The invention also relates to a device or an apparatus for performing these operations. All flowcharts presented herein represent computer implemented steps and/or are visual representations of algorithms implemented by the system. The apparatus can be specially constructed for the required purpose, such as a special purpose computer. When defined as a special purpose computer, the computer can also perform other processing, program execution or routines that are not part of the special purpose, while still being capable of operating for the special purpose. Alternatively, the operations can be processed by a general-purpose computer selectively activated or configured by one or more computer programs stored in the computer memory, cache, or obtained over a network. When data is obtained over a network the data can be processed by other computers on the network, e.g. a cloud of computing resources.

The embodiments of the invention can also be defined as a machine that transforms data from one state to another state. The data can represent an article, that can be represented as an electronic signal and electronically manipulate data. The transformed data can, in some cases, be visually depicted on a display, representing the physical object that results from the transformation of data. The transformed data can be saved to storage generally, or in particular formats that enable the construction or depiction of a physical and tangible object. In some embodiments, the manipulation can be performed by a processor. In such an example, the processor thus transforms the data from one thing to another. Still further, some embodiments include methods can be processed by one or more machines or processors that can be connected over a network. Each machine can transform data from one state or thing to another, and can also process data, save data to storage, transmit data over a network, display the result, or communicate the result to another machine. Computer-readable storage media, as used herein, refers to physical or tangible storage (as opposed to signals) and includes without limitation volatile and non-volatile, removable and non-removable storage media implemented in any method or technology for the tangible storage of information such as computer-readable instructions, data structures, program modules or other data.

Although method operations are presented in a specific order according to some embodiments, the execution of those steps do not necessarily occur in the order listed unless explicitly specified. Also, other housekeeping operations can be performed in between operations, operations can be adjusted so that they occur at slightly different times, and/or operations can be distributed in a system which allows the occurrence of the processing operations at various intervals associated with the processing, as long as the processing of the overlay operations are performed in the desired way and result in the desired system output.

It will be appreciated by those skilled in the art that while the invention has been described above in connection with particular embodiments and examples, the invention is not necessarily so limited, and that numerous other embodiments, examples, uses, modifications and departures from the embodiments, examples and uses are intended to be encompassed by the claims attached hereto. The entire disclosure of each patent and publication cited herein is incorporated by reference, as if each such patent or publication were individually incorporated by reference herein. Various features and advantages of the invention are set forth in the following claims.

1. A system for multiphase meter anomaly detection comprising:
one or more electrical meters, and
one or more power lines;
wherein the one or more power lines are configured to transmit electrical power to the one or more electrical meters;
wherein the one or more electrical meters are configured to detect the presence of multiple phases within the electrical power;
wherein each of the one or more electrical meters comprise one or more meter computers comprising one or more meter processors and one or more meter non-transitory computer readable media, the one or more meter non-transitory computer readable media comprising instructions stored thereon that when executed cause the one or more computers to:
generate, by the one or more meter processors, an anomaly signal associated with at least one phase of the multiple phases even if one or more other phases of the multiple phases are still energized.

2. The system of claim 1,
wherein the system is configured to use an internal anomaly detection alert from the one or more meters to generate the anomaly signal.

3. The system of claim 2,
wherein the system is able to detect a wire down condition comprising a deenergized power line in a 3 wire electrical distribution system.

4. The system of claim 3,
wherein the 3 wire distribution system comprises 3 phases and no neutral wire

5. The system of claim 2,
wherein the system is able to detect a wire down condition comprising a deenergized power line in a 4 wire distribution system.

6. The system of claim 5,
wherein the 4 wire distribution system comprises 3 phases and a neutral wire,

7. The system of claim 1,
wherein the one or more electrical meters comprises one or more smart meters; and
wherein the system is configured to use the one or more smart meters to detect a location of a broken electrical utility component on an electrical distribution circuit.

8. The system of claim 7,
wherein the electrical distribution circuit includes one or more electrical utility components located external to the one or more smart meter's internal components.

9. The system of claim 1,
wherein the one or more electrical meters are a 3 phase electrical meters; and
wherein the system is configured to use discovery signals from one or more electrical meters to determine if one of the phases has lost voltage.

10. The system of claim 1,
wherein the instructions cause the one or more smart meter computers to send, by one or more meter processors, unsolicited messages when abnormal conditions are detected.

11. The system of claim 1,
wherein each of the one or more electrical meters comprises a circuit board comprising a plurality of input pins; and
wherein the one or more meter computers are configured to monitor an active and inactive status of at least one of the plurality of input pins through a discovery signal.

12. The system of claim 11,
wherein the discovery signals are used to detect partial out circuits on a 3 wire distribution circuit.

13. The system of claim 11,
wherein the discovery signals are used to detect partial out circuits on 4 wire distribution circuits

14. The system of claim 11,
wherein the at least one of the input pins is configured to detect a voltage fluctuation and/or voltage outages occurring in one or more input phases.

15. The system of claim 11,
wherein the meter computer is configured to identify an abnormal power condition using a signal from at least one of the plurality of input pins.

16. The system of claim 1,
wherein the system is configured to determine an approximate location of a power loss in a power line using one or more electrical meters.

17. The system of claim 1,
wherein the one or more electrical meters comprise two or more electrical meters; and
wherein the system is configured to determine an approximate location of a power loss in a power line using the two or more electrical meters.

18. The system of claim 17,
wherein the one or more power lines transmit electrical power from an electrical power source upstream through one or more electrical components located at various locations to a downstream electrical power sink;
wherein at least a first electrical meter of the two or more electrical meters is located upstream of the approximate location; and
wherein at least a second electrical meter of the two or more electrical meters is located downstream of the approximate location.

19. The system of claim 1,
wherein the system is configured not send the anomaly signal if a partial voltage event is logged for less than a predetermined period of time.

20. The system of claim 19,
wherein the instructions are configured to send the anomaly signal to a command center; and
wherein the command center comprises one or more command center computers comprising one or more command center processors and one or more command center non-transitory computer readable media, wherein the one or more command center computers are configured to monitor and/or control one or more components in an electrical distribution system.
